(19) United States
(12) Patent Application Publication
(10) Pub. No.: US 2011/0057221 A1
(43) Pub. Date: Mar. 10, 2011

(54) ORGANIC ELECTROLUMINESCENCE DEVICE AND METHOD FOR PRODUCING THE SAME

(76) Inventor: Shinichiro SONODA, Ashigarakami-gun (JP)

(21) Appl. No.: 12/873,828

(22) Filed: Sep. 1, 2010

(30) Foreign Application Priority Data
Sep. 4, 2009 (JP) 2009-204807

(51) Int. Cl. H01L 33/60; H01L 33/00

(52) U.S. Cl. 257/98; 438/29; 257/E33.073; 257/E33.001

(57) ABSTRACT

To provide an organic electroluminescence device including: an organic electroluminescence portion which includes at least an anode, a light-emitting layer and a cathode; a sealing layer which covers a surface of the cathode of the organic electroluminescence portion; a lens which is provided over the sealing layer and controls an optical path of light emitted from the light-emitting layer; and a low-refractive-index layer provided between the sealing layer and the lens, wherein the low-refractive-index layer has a refractive index lower than a refractive index of the sealing layer.

### BACKGROUND OF THE INVENTION

1. Field of the Invention

The present invention relates to an organic electroluminescence device (also referred to as “organic electroluminescence display device”, “organic EL device” or “organic EL display device”) which has high light extraction efficiency and a single-peak luminance angular distribution and which reduces color difference in a viewing angle range and thus exhibits less hue change, and a method for producing the organic electroluminescence device.

2. Description of the Related Art

The organic electroluminescence device is a self-light-emitting display device and is used for display, lighting, etc. The organic EL display has advantages in terms of display performance, such as high visibility and less viewing angle dependence, in comparison with conventional CRTs or LCDs. Also, it has such advantages that the display can be reduced in weight and thickness. As well as having advantages in terms of reduction in weight and thickness, the organic EL lighting has the potential to realize lighting in a heretofore unrealizable form by the use of a flexible substrate.

As just described, the organic electroluminescence device has excellent characteristics. However, in general, the refractive indices of layers constituting the display device, including a light-emitting layer, are higher than the refractive index of air. For example, in the organic electroluminescence device, the refractive index of a thin organic layer such as a light-emitting layer is in the range of 1.6 to 2.1. Thus, emitted light is liable to be totally reflected at the interface, and the light extraction efficiency is less than 20%, which means that most of the light is lost.

For example, an organic electroluminescence portion in a generally known organic electroluminescence device includes a substrate and also includes, over this substrate, a pair of electrode layers and organic compound layer(s) placed between the electrode layers. The organic compound layer(s) include(s) a light-emitting layer, and the organic electroluminescence device allows light emitted by the light-emitting layer to discharge from the light extraction surface side. In this case, it is impossible to extract totally reflected light components (which are light components reflected at a critical angle or greater) at the light extraction surface or at the interface between the electrode layer and the organic compound layer, so that there is a problem of low light extraction efficiency.

Accordingly, to improve light extraction efficiency, there has been proposed a variety of organic electroluminescence devices wherein an optical path of light emitted by a light-emitting layer is controlled, and a light-extracting member (such as a lens) which allows the light emitted by the light-emitting layer to discharge from the light extraction surface side is placed over the optical path.

Japanese Patent Application Laid-Open (JP-A) No. 2003-272873 proposes an organic EL head including a substrate, a reflective layer formed on the substrate, an anode formed on the reflective layer, an organic EL light-emitting layer formed on the anode, and a cathode formed of a thin metal film (with a thickness that allows light to pass through the film), one surface of which is attached to the light-emitting layer and the other surface of which is covered with a semitransparent reflective layer, wherein the reflective layer and the semitransparent reflective layer constitute a micro-optical resonator (microcavity), and a microlens is formed on the outside of the semitransparent reflective layer.

This proposal uses the organic EL head as a writing unit of an image forming apparatus.

JP-A No. 2004-227940 proposes a display including electrodes, a light-emitting element placed between the electrodes, a light-emitting layer which allows the light-emitting element to emit light upon application of voltage between the electrodes, and a lens layer that has at least one microlens formed in a position (within the length of one side of the light-emitting element) over the electrode with respect to the light emission direction in which the light emitted from the light-emitting element is output, wherein the microlens has a diameter greater than that of the light-emitting element.

As a result of carrying out a series of earnest examinations, the present inventors have found that the luminous intensity distribution (light angular distribution) of an organic electroluminescence device greatly varies depending upon the element design and that the structure of a lens (which is a light-extracting member) suitable for light extraction varies depending upon the luminous intensity distribution, as described later.

In related art, however, these facts are not considered at all, and thus light extraction efficiency is not optimized. In other words, despite the fact that the most suitable diameter of a lens used in combination with an organic electroluminescence portion varies depending upon the structure of the organic electroluminescence portion, optimization of the combination of the structure of the organic electroluminescence portion and the lens is not carried out, and consequently, sufficient light extraction efficiency is not obtained.

Also, regarding a display, a lens structure suitable for a luminous intensity distribution is required in order for the luminance change and the chromaticity change to be appropriate when the viewing angle is changed. To improve the light extraction efficiency for the display, it is important to increase front luminance. To increase front luminance, it is desirable that the refractive index of the lens be high; however, there is a problem in that high-angle light in the organic electroluminescence portion or in a sealing layer (which is not intended to be discharged to the outside) is discharged to the outside and consequently the luminance distribution has a plurality of peaks.

Accordingly, in reality, there is much need for an organic electroluminescence device which has high light extraction efficiency and a single-peak luminance angular distribution and which reduces color difference in a viewing angle range and thus exhibits less hue change, and a method for producing the organic electroluminescence device.

### BRIEF SUMMARY OF THE INVENTION

The present invention provides an organic electroluminescence device which has high light extraction efficiency and a single-peak luminance angular distribution and which reduces color difference in a viewing angle range and thus exhibits less hue change, and a method for producing the organic electroluminescence device.

As a result of carrying out a series of earnest examinations to solve the above-mentioned problems, the present inventors have found that when a microlens is provided over an organic electroluminescence portion having a secondary or higher microcavity structure, it is effective to form a low-refractive-index layer on a sealing layer which covers a surface of a cathode of the organic electroluminescence portion. Specifically, when the low-refractive-index layer is provided on the sealing layer so as to satisfy the relationships np>nf and nL>nf (where np denotes the refractive index of the sealing layer, nL denotes the refractive index of the lens, and of denotes the refractive index of the low-refractive-index layer), at least light responsible for a secondary peak on the high angle side is totally reflected upon entry from the organic electroluminescence portion to the low-refractive-index layer. Tertiary and higher peaks are removed at the same time because they are present at higher angles than the angle at which the secondary peak is present. Thus, light responsible for a secondary or higher peak on the high angle side does not enter the low-refractive-index layer, and so the luminance angular characteristic has a single peak. Light responsible for a secondary or higher peak on the high angle side has many wavelength components which are different from those of light on the low angle side. As a result, it has been found that light responsible for a secondary or higher peak on the high angle side does not pass through the low-refractive-index layer, let alone enter the lens, and thus color difference can be reduced.

When the refractive index of the lens provided over the sealing layer which covers the surface of the cathode of the organic electroluminescence portion is lowered, the front luminance lowers. However, it has been found that when the low-refractive-index layer is provided and the refractive index of the lens is increased, unnecessary light responsible for a secondary or higher peak on the high angle side can be removed maintaining the front luminance.

The present invention is based upon the above-mentioned findings of the present inventors, and means for solving the problems are as follows.

<1> An organic electroluminescence device including: an organic electroluminescence portion which includes at least an anode, a light-emitting layer and a cathode; a sealing layer which covers a surface of the cathode of the organic electroluminescence portion; a lens which is provided over the sealing layer and controls an optical path of light emitted from the light-emitting layer; and a low-refractive-index layer provided between the sealing layer and the lens, wherein the low-refractive-index layer has a refractive index lower than a refractive index of the sealing layer.
<2> The organic electroluminescence device according to <1>, wherein the low-refractive-index layer is a solid layer having a low refractive index.
<3> The organic electroluminescence device according to <1>, wherein the lens has a refractive index higher than the refractive index of the low-refractive-index layer.
<4> The organic electroluminescence device according to <1>, wherein a luminous intensity distribution in the sealing layer has a plurality of peaks, and wherein a peak angle θp of the sealing layer with respect to a higher angle side than a main peak, and a total reflection angle θm of the sealing layer calculated as θm=sin⁻¹(nf/np) satisfy the relationship θm<θp, where np denotes the refractive index of the sealing layer, and of denotes the refractive index of the low-refractive-index layer.
<5> The organic electroluminescence device according to <1>, wherein the ratio of an effective diameter φ of the lens to a distance d between the cathode of the organic electroluminescence portion and the lens, represented by φ/d, is 2 or greater.
<6> The organic electroluminescence device according to <1>, wherein the organic electroluminescence portion has a secondary microcavity structure having an optical length L(λ) of 2λ, where λ denotes an emission wavelength.
<7> The organic electroluminescence device according to <1>, wherein the organic electroluminescence portion has a tertiary microcavity structure having an optical length L(λ) of 3λ, where λ denotes an emission wavelength.
<8> The organic electroluminescence device according to <1>, wherein the low-refractive-index layer contains a fluorine-containing material.
<9> A method for producing an organic electroluminescence device, including: forming a low-refractive-index layer on a sealing layer which covers a surface of a cathode of an organic electroluminescence portion; and forming a lens on a surface of the low-refractive-index layer, wherein the organic electroluminescence device includes: the organic electroluminescence portion which includes at least an anode, a light-emitting layer and the cathode; the sealing layer which covers the surface of the cathode of the organic electroluminescence portion; the lens which is provided over the sealing layer and controls an optical path of light emitted from the light-emitting layer; and the low-refractive-index layer provided between the sealing layer and the lens, and wherein the low-refractive-index layer has a refractive index lower than a refractive index of the sealing layer.
<10> The method according to <9>, wherein the lens is formed by imprinting.
<11> The method according to <9>, wherein the lens is formed by ink jetting.

The present invention makes it possible to solve the problems in related art and provide an organic electroluminescence device which has high light extraction efficiency and a single-peak luminance angular distribution and which reduces color difference in a viewing angle range and thus exhibits less hue change, and a method for producing the organic electroluminescence device.

### BRIEF DESCRIPTION OF THE DRAWINGS

FIG. 1 is a schematic drawing showing an example of an organic electroluminescence device of the present invention.

FIG. 2A is a top view showing an example of an organic electroluminescence device of the present invention.

FIG. 2B is a front elevational view showing an example of an organic electroluminescence device of the present invention.

FIG. 3 is a drawing showing a relationship between a sealing layer and a low-refractive-index layer with respect to optical refraction.

FIG. 4 is a diagram showing a luminous intensity distribution of an organic electroluminescence element (1) of Production Example 1.

FIG. 5 is a diagram showing a luminous intensity distribution of an organic electroluminescence element (2) of Production Example 2.

FIG. 6A is a graph showing the wavelength dependence of a luminous intensity distribution.

FIG. 6B is a graph showing the wavelength dependence of a luminous intensity distribution when the wavelength of 510 nm shown in FIG. 6A is set at 1.00.

FIG. 7 is a diagram showing luminous intensity distributions of organic electroluminescence devices of Nos. 1, 2, 3, 4 and 5.

FIG. 8 is a diagram showing luminous intensity distributions of organic electroluminescence devices of Nos. 2 and 6.

FIG. 9 is a diagram showing luminous intensity distributions of organic electroluminescence devices of Nos. 3 and 7.

FIG. 10 is a diagram showing luminous intensity distributions of organic electroluminescence devices of Nos. 4 and 8.

FIG. 11 is a diagram showing luminous intensity distributions of organic electroluminescence devices of Nos. 1, 2 and 6 each incorporating an organic electroluminescence element (2) of Production Example 2.

FIG. 12 is a process drawing showing a method for producing lenses on a low-refractive-index layer by imprinting.

FIG. 13 is a process drawing showing a method for producing lenses on a low-refractive-index layer by ink jetting.

FIG. 14 is a graph showing a result of an examination in which the angular distribution of light intensity is examined changing the ratio (φ/d) of an effective diameter φ of a lens to a distance d between a cathode of an organic electroluminescence portion and the lens.

FIG. 15 is a drawing showing a state in which lenses are placed over three-color pixels of red (R), green (G) and blue (B).

FIG. 16 is a drawing showing a state in which lenses are placed over three-color pixels of red (R), green (G) and blue (B).

FIG. 17 is a drawing showing how to measure the maximum length “a” of one side of a pixel (light-emitting layer), when the pixel is rectangular.

FIG. 18 is a drawing showing a state in which a lens is placed over a square pixel.

FIG. 19 is a drawing showing a state in which a lens is placed over a rectangular pixel.

FIG. 20 is a drawing showing a state in which a lens is placed over a circular pixel.

FIG. 21 is a drawing showing a state in which a lens is placed over a triangular pixel.

### DETAILED DESCRIPTION OF THE INVENTION

### Organic Electroluminescence Device

An organic electroluminescence device of the present invention includes an organic electroluminescence portion, a sealing layer, a lens, and a low-refractive-index layer provided between the sealing layer and the lens. If necessary, the organic electroluminescence device may further include other component(s).

### <Low-Refractive-Index Layer>

The low-refractive-index layer has a refractive index lower than a refractive index of the sealing layer.

The low-refractive-index layer is preferably a solid layer having a low refractive index. The low-refractive-index layer should not be an air layer.

The lens preferably has a refractive index higher than the refractive index of the low-refractive-index layer. When the lens has a refractive index lower than or equal to the refractive index of the low-refractive-index layer, high-angle light components reflected by the lens advance at lower angles than high-angle light components reflected by the low-refractive-index layer, so that the provision of the low-refractive-index layer is meaningless. In this case, there is a problem in that, due to the low refractive index of the lens, the refracting power is weak, and thus the front luminance does not increase much.

Accordingly, the relationships np>nf and nL>nf (where np denotes the refractive index of the sealing layer, nL denotes the refractive index of the lens, and nf denotes the refractive index of the low-refractive-index layer) are satisfied.

The refractive index nf of the low-refractive-index layer is preferably in the range of 1.01 to 1.5, more preferably 1.3 to 1.5. There is no practical method for making the refractive index lower than 1.01 in the case of a solid layer. When the refractive index is greater than 1.5, unnecessary high-angle light components may be unable to be sufficiently removed.

The low-refractive-index layer is not particularly limited as long as it satisfies the above-mentioned relationships concerning the refractive indices. The shape, structure, size, etc. of the low-refractive-index layer may be suitably selected. The low-refractive-index layer is preferably shaped like a film or a plate. The structure of the low-refractive-index layer may be a single-layer structure or a laminated structure. The size of the low-refractive-index layer may be suitably selected according to the size of an organic electroluminescence element.

The material for the low-refractive-index layer is not particularly limited and may be suitably selected according to the intended purpose. Suitable examples of the material include fluorine-containing materials. The fluorine-containing materials may be organic fluorine-containing materials or inorganic fluorine-containing materials. Examples of the organic fluorine-containing materials include fluorine resins, (C₆F₁₀O)n (n denotes the number of times the repeat unit is repeated), (CF₂CF₂)n (n denotes the number of times the repeat unit is repeated) and C₄F₉OCH₃. Examples of the inorganic fluorine-containing materials include MgF₂, YF₃ and CaF₂. Among these, fluorine resins and (C₆F₁₀O)n are particularly preferable in that their refractive indices are as low as approximately 1.3.

The method for producing the low-refractive-index layer is not particularly limited and may be suitably selected according to the intended purpose. The low-refractive-index layer can be particularly favorably produced by the after-mentioned method of the present invention for producing an organic electroluminescence device.

The low-refractive-index layer preferably has a thickness of 0.5 μm to 5 μm, more preferably 1 μm to 3 μm.

In the present invention, the organic electroluminescence portion preferably has a microcavity structure because the front luminance increases in a state where a lens is not attached.

Here, the microcavity structure means a structure in which a semipermeable layer on the light emission side and a reflective electrode layer on the side opposite to the light emission side interfere with each other.

The organic electroluminescence portion preferably has a secondary microcavity structure having an optical length L(λ) of 2λ(λ denotes an emission wavelength), or a tertiary microcavity structure having an optical length L(λ) of 3λ (λ denotes an emission wavelength). Employment of a secondary (2λ) or tertiary (3λ) microcavity structure is most suitable for the following reasons: in the case of a primary (1λ) microcavity structure, thickness control is difficult; in the case of a quaternary (4λ) or higher microcavity structure, thickness control is easy but the front luminance decreases.

The secondary microcavity structure means that the optical length is the second shortest, in comparison with the shortest optical length which allows intensification of light traveling in a round-trip manner between metal reflective layers.

The tertiary microcavity structure means that the optical length is the third shortest, in comparison with the shortest optical length which allows intensification of light traveling in a round-trip manner between metal reflective layers.

Here, the optical length (optical distance) L of the microcavity structure is represented by the equation L=2×Σnᵢdᵢ (i denotes a mixed number composed of integers of 1 to i) and a reflection phase shift, or more specifically, the sum of products of the thickness d of each layer (formed between an anode and a cathode) and the refractive index n of the layer.

The relationship between the optical length L and the emission wavelength λ is as follows: L(λ)=mλ (when m=1, it means that a primary microcavity structure is employed; when m=2, it means that a secondary microcavity structure is employed; when m=3, it means that a tertiary microcavity structure is employed). The optical length L(λ) is represented by the following equation.

In the above equation, L(λ) denotes an optical length [=2Σnⱼdⱼ+ΣABS(φₘᵢλ/2π)], λ denotes an emission wavelength, i denotes a suffix showing a metal reflective layer, and j denotes a suffix showing a layer (an organic layer, a dielectric layer, etc.) between metal layers, other than a metal reflective layer.

In the present invention, it is preferred that a luminous intensity distribution in the sealing layer have a plurality of peaks, and that a peak angle θp of the sealing layer with respect to a higher angle side than a main peak, and a total reflection angle (critical angle) θm of the sealing layer calculated as θm=sin⁻¹(nf/np) satisfy the relationship θm<θp (where np denotes the refractive index of the sealing layer, and nf denotes the refractive index of the low-refractive-index layer), because the luminance characteristic does not have a plurality of peaks. When θm is greater than or equal to θp, the luminance characteristic may have a plurality of peaks.

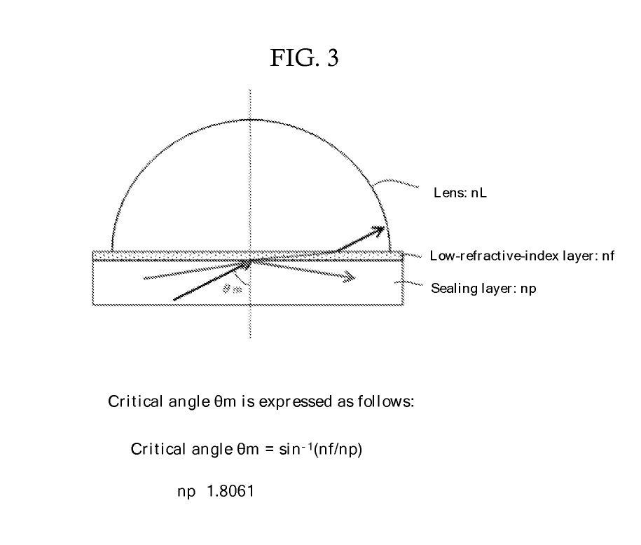

Here, in the case where a low-refractive-index layer is inserted between a lens and a sealing layer as shown in FIG. 3, when the angle at which light advances from the sealing layer to the low-refractive-index layer is greater than or equal to the critical angle θm, the light is reflected and thus does not enter the low-refractive-index layer. Specifically, when the low-refractive-index layer is provided so as to satisfy the relationships np>nf and nL>nf (where np denotes the refractive index of the sealing layer, nL denotes the refractive index of the lens, and nf denotes the refractive index of the low-refractive-index layer), the angle at which light advances from the sealing layer to the low-refractive-index layer is greater than or equal to the critical angle, and thus light responsible for a secondary peak on the high angle side is totally reflected upon entry from the sealing layer to the low-refractive-index layer. Therefore, light responsible for a secondary peak on the high angle side does not enter the low-refractive-index layer, and so the luminance angular characteristic has a single peak.

In the present invention, the ratio (φ/d) of an effective diameter φ of the lens to a distance d between the cathode of the organic electroluminescence portion and the lens is preferably 2 or greater. When the ratio (φ/d) is less than 2, light may vaguely spread to adjacent pixels, the luminance may decrease with a slight angle, and the front luminance may not increase.

### <Organic Electroluminescence Portion>

The organic electroluminescence portion includes at least an anode, a light-emitting layer and a cathode. If necessary, the organic electroluminescence portion may further include a hole injection layer, a hole transport layer, an electron injection layer, an electron transport layer, etc. Additionally, these layers may have other functions. Each layer may be formed of a material selected from a variety of materials.

### —Anode—

The anode supplies holes to the hole injection layer, the hole transport layer, the light-emitting layer, etc. The material for the anode may be selected from metals, alloys, metal oxides, electroconductive compounds, and mixtures of these, and preference is given to materials which are 4 eV or more in work function. Specific examples of such materials include conductive metal oxides such as tin oxide, zinc oxide, indium oxide and indium tin oxide (ITO); metals such as gold, silver, chromium and nickel; mixtures or laminated products of the metals and the conductive metal oxides; inorganic conductive materials such as copper iodide and copper sulfide; organic conductive materials such as polyaniline, polythiophenes and polypyrroles; and laminated products of these materials and ITO. Among these, conductive metal oxides are preferable, and ITO is particularly preferable in terms of productivity, conductivity, transparency and so forth.

The thickness of the anode is not particularly limited and may be suitably selected according to the material used for the anode; however, it is preferably in the range of 10 nm to 5 μm, more preferably 50 nm to 1 μm, even more preferably 100 nm to 500 nm.

The anode is generally a layer formed over a substrate such as a soda-lime glass substrate, alkali-free glass substrate or transparent resin substrate.

The thickness of the substrate is not particularly limited as long as favorable mechanical strength can be maintained. In the case where glass is used as the substrate, its thickness is preferably 0.2 mm or greater, more preferably 0.7 mm or greater.

A barrier film may be used as the transparent resin substrate. The barrier film is a film including a plastic support and a gas-impermeable barrier layer provided on the plastic support. Examples of the barrier film include a barrier film produced by vapor deposition of silicon oxide or aluminum oxide (Japanese Patent Application Publication (JP-B) No. 53-12953 and JP-A No. 58-217344), a barrier film including an organic-inorganic hybrid coating layer (JP-A Nos. 2000-323273 and 2004-25732), a barrier film including an inorganic layer compound (JP-A No. 2001-205743), a barrier film in which inorganic material is layered (JP-A Nos. 2003-206361 and 2006-263989), a barrier film in which organic and inorganic layers are alternately stacked (JP-A No. 2007-30387, U.S. Pat. No. 6,413,645, and Thin Solid Films authored by Affinito et al., 1996, pp. 290-291), and a barrier film in which organic and inorganic layers are continuously stacked (U.S. Patent Application Publication No. 2004-46497).

The method for producing the anode may be selected from a variety of methods according to the material used for the anode. In the case of ITO, for example, a layer is formed by a method such as an electron beam method, sputtering, resistance heating vapor deposition, a chemical reaction method (e.g. a sol-gel method) or application of a dispersion of indium tin oxide. Also, by subjecting the anode to washing or other treatment, the drive voltage of a display device can be reduced, and luminous efficiency can be enhanced. In the case of ITO, for example, UV-ozone treatment or the like is effective.

### —Cathode—

The cathode supplies electrons to the electron injection layer, the electron transport layer, the light-emitting layer, etc. and is selected in view of its stability, ionization potential and adhesion to adjacent layer(s) such as the electron injection layer, the electron transport layer, the light-emitting layer, etc.

Examples of the material for the cathode include metals, alloys, metal oxides, electroconductive compounds, and mixtures of these. Specific examples of the material include alkali metals (such as Li, Na and K) and fluorides thereof, alkaline earth metals (such as Mg and Ca) and fluorides thereof, gold, silver, lead, aluminum, alloys or mixed metals of sodium and potassium, alloys or mixed metals of lithium and aluminum, alloys or mixed metals of magnesium and silver, indium, and rare earth metals (such as ytterbium). Among these, materials which are 4 eV or less in work function are preferable, particularly aluminum, alloys or mixed metals of lithium and aluminum, and alloys or mixed metals of magnesium and silver.

The thickness of the cathode is not particularly limited and may be suitably selected according to the material used for the cathode; however, it is preferably in the range of 10 nm to 5 μm, more preferably 50 nm to 1 μm, even more preferably 100 nm to 1 μm.

The cathode is produced by a method such as an electron beam method, sputtering, resistance heating vapor deposition or a coating method. A single metal may be vapor-deposited, or two or more metals may be simultaneously vapor-deposited. Further, a plurality of metals may be simultaneously vapor-deposited so as to form an alloy electrode. Alternatively, a previously prepared alloy may be vapor-deposited.

The sheet resistances of the anode and the cathode are preferably low, or more specifically, preferably several hundred ohms per square or less each.

### —Light-Emitting Layer—

The material for the light-emitting layer is not particularly limited and may be suitably selected according to the intended purpose. Examples of the material include materials which can form layers having functions such as a function of being injected with holes from the anode or the hole injection/transport layer and being injected with electrons from the cathode or the electron injection/transport layer when an electric field is applied, a function of transferring an injected charge, and a function of providing places for recombination of holes and electrons and thus effecting light emission.

Specific examples of the material for the light-emitting layer include benzoxazole derivatives, benzimidazole derivatives, benzothiazole derivatives, styrylbenzene derivatives, polyphenyl derivatives, diphenylbutadiene derivatives, tetraphenylbutadiene derivatives, naphthalimide derivatives, coumarin derivatives, perylene derivatives, perinone derivatives, oxadiazole derivatives, aldazine derivatives, pyrrolidine derivatives, cyclopentadiene derivatives, bisstyrylanthracene derivatives, quinacridone derivatives, pyrrolopyridine derivatives, thiadiazolopyridine derivatives, styrylamine derivatives, aromatic dimethylidyne compounds, metal complexes typified by metal complexes of 8-quinolinol derivatives and rare earth complexes, and polymer compounds such as polythiophene, polyphenylene and polyphenylene vinylene. These may be used individually or in combination.

The thickness of the light-emitting layer is not particularly limited and may be suitably selected according to the intended purpose. It is preferably in the range of 1 nm to 5 μm, more preferably 5 nm to 1 μm, even more preferably 10 nm to 500 nm.

The method for forming the light-emitting layer is not particularly limited and may be suitably selected according to the intended purpose. Examples thereof include methods such as resistance heating vapor deposition, an electron beam method, sputtering, molecular lamination, coating methods (e.g. spin coating, casting, and dip coating) and the LB (Langmuir-Blodgett) method. Among these, resistance heating vapor deposition and coating methods are particularly preferable.

### —Hole Injection Layer and Hole Transport Layer—

The material(s) for the hole injection layer and the hole transport layer is/are not particularly limited as long as it/they has/have any of a function of being injected with holes from the anode, a function of transporting holes and a function of serving as a barrier against electrons injected from the cathode, and the material(s) may be suitably selected according to the intended purpose.

Examples of the material(s) for the hole injection layer and the hole transport layer include carbazole derivatives, triazole derivatives, oxazole derivatives, oxadiazole derivatives, imidazole derivatives, polyarylalkane derivatives, pyrazoline derivatives, pyrazolone derivatives, phenylenediamine derivatives, arylamine derivatives, amino-substituted chalcone derivatives, styrylanthracene derivatives, fluorenone derivatives, hydrazone derivatives, stylbene derivatives, silazane derivatives, aromatic tertiary amine compounds, styrylamine compounds, aromatic dimethylidene compounds, porphyrin compounds, polysilane compounds, poly(N-vinylcarbazole) derivatives, aniline copolymers, and conductive high molecular oligomers such as thiophene oligomers and polythiophene. These may be used individually or in combination.

The hole injection layer and the hole transport layer may have a single-layer structure including one material or two or more materials selected from the above-mentioned materials, or may have a multilayered structure including a plurality of layers of a single component or different components.

The hole injection layer and the hole transport layer may, for example, be formed by vacuum vapor deposition, the LB method, or a coating method (spin coating, casting, dip coating, etc.) in which a hole injection/transport agent is dissolved or dispersed in solvent and thusly applied. When a coating method is employed, the hole injection/transport agent may be dissolved or dispersed along with resin component(s).

The resin component(s) is/are not particularly limited and may be suitably selected according to the intended purpose. Examples thereof include polyvinyl chloride resins, polycarbonate resins, polystyrene resins, polymethyl methacrylate resins, polybutyl methacrylate resins, polyester resins, polysulfone resins, polyphenylene oxide resins, polybutadiene, poly(N-vinylcarbazole) resins, hydrocarbon resins, ketone resins, phenoxy resins, polyamide resins, ethyl cellulose, vinyl acetate resins, ABS resins, polyurethane resins, melamine resins, unsaturated polyester resins, alkyd resins, epoxy resins and silicone resins. These may be used individually or in combination.

The thickness of the hole injection layer and the thickness of the hole transport layer are not particularly limited and may be suitably selected according to the intended purpose but are preferably in the range of 1 nm to 5 μm each, more preferably 5 nm to 1 μm each, even more preferably 10 nm to 500 nm each.

### —Electron Injection Layer and Electron Transport Layer—

The material(s) for the electron injection layer and the electron transport layer is/are not particularly limited as long as it/they has/have any of a function of being injected with electrons from the cathode, a function of transporting electrons and a function of serving as a barrier against holes injected from the anode, and the material(s) may be suitably selected according to the intended purpose.

Examples of the material(s) for the electron injection layer and the electron transport layer include triazole derivatives, oxazole derivatives, oxadiazole derivatives, fluorenone derivatives, anthraquinodimethane derivatives, anthrone derivatives, diphenylquinone derivatives, thiopyran dioxide derivatives, carbodiimide derivatives, fluorenylidenemethane derivatives, distyrylpyrazine derivatives, heterocyclic tetracarboxylic acid anhydrides (such as naphthaleneperylene), phthalocyanine derivatives, and metal complexes typified by metal complexes of 8-quinolinol derivatives and metal complexes with ligands being metal phthalocyanine, benzoxazole, benzothiazole, etc. These may be used individually or in combination.

The electron injection layer and the electron transport layer may have a single-layer structure including one material or two or more materials selected from the above-mentioned materials, or may have a multilayered structure including a plurality of layers of a single component or different components.

The electron injection layer and the electron transport layer may, for example, be formed by vacuum vapor deposition, the LB method, or a coating method (spin coating, casting, dip coating, etc.) in which an electron injection/transport agent is dissolved or dispersed in solvent and thusly applied. When a coating method is employed, the electron injection/transport agent may be dissolved or dispersed along with resin component(s). The resin component(s) may, for example, be selected from the examples mentioned above in relation to the hole injection layer and the hole transport layer.

The thickness of the electron injection layer and the thickness of the electron transport layer are not particularly limited and may be suitably selected according to the intended purpose but are preferably in the range of 1 nm to 5 μm each, more preferably 5 nm to 1 μm each, even more preferably 10 nm to 500 nm each.

### <Lens>

The lens has a function of controlling an optical path of light emitted from the light-emitting layer.

The lens is formed on the low-refractive-index layer which is formed on the sealing layer which covers a surface of the cathode of the organic electroluminescence portion.

The shape, placement, size, material, etc. of the lens are not particularly limited and may be suitably selected according to the intended purpose. The lens may, for example, be shaped like a sphere, a hemisphere, an ellipse, a trapezoid or the like. It is particularly preferred that the lens be shaped like a hemisphere in terms of increase in front luminance.

Examples of the lens placement include lens placement in the form of a square lattice, and lens placement in the form of a honeycomb.

Examples of the material for the lens include transparent resins, glasses, transparent crystals and transparent ceramics.

As for the size of the lens (in the case of a hemispherical lens), the lens preferably has an effective diameter of 10 μm to 1,000 μm, more preferably 20 μm to 200 μm.

The lens preferably has a refractive index nL of 1.3 to 1.8, more preferably 1.4 to 1.7.

### <Sealing Layer>

The sealing layer is a layer which covers the surface of the cathode of the organic electroluminescence portion.

The sealing layer is not particularly limited as long as it has a function of preventing permeation of oxygen, moisture, nitrogen oxides, sulfur oxides and ozone in the air, and the sealing layer may be suitably selected according to the intended purpose.

The surface of the cathode is conceived as including the surface (exposed surface) of the organic electroluminescence portion as well as the surface of the cathode.

The material for the sealing layer is not particularly limited and may be suitably selected according to the intended purpose. Examples thereof include SiN and SiON.

The method for forming the sealing layer is not particularly limited and may be suitably selected according to the intended purpose. Examples thereof include CVD and vacuum vapor deposition.

The thickness of the sealing layer is not particularly limited and may be suitably selected according to the intended purpose; however, it is preferably in the range of 5 nm to 5,000 nm, more preferably 7 nm to 3,000 nm. When the thickness of the sealing layer is less than 5 nm, the sealing layer's barrier function with which to prevent permeation of oxygen and moisture in the air may be insufficient. When the thickness of the sealing layer is greater than 5,000 nm, there may be a decrease in light transmittance and degradation of transparency.

As for an optical property of the sealing layer, the sealing layer preferably has a light transmittance of 80% or greater, more preferably 85% or greater, even more preferably 90% or greater.

The sealing layer preferably has a refractive index np of 1.5 to 1.9, more preferably 1.7 to 1.8.

### —Substrate—

Regarding the above-mentioned substrate, its shape, structure, size, etc. may be suitably selected. In general, the substrate is preferably shaped like a plate. The structure of the substrate may be a single-layer structure or a laminated structure. Also, the substrate may be formed of a single member or of two or more members. The substrate may be colorless and transparent or may be colored and transparent; however, it is preferred that the substrate be colorless and transparent because light emitted from the light-emitting layer is not scattered, attenuated, etc.

The material for the substrate is not particularly limited and may be suitably selected according to the intended purpose. Examples thereof include inorganic materials such as yttria-stabilized zirconia (YSZ) and glass; polyester resins such as polyethylene terephthalate resins, polybutylene phthalate resins and polyethylene naphthalate resins; and organic materials such as polystyrene resins, polycarbonate resins, polyethersulfone resins, polyarylate resins, polyimide resins, polycycloolefin resins, norbornene resins and poly(chlorotrifluoroethylene) resins. These may be used individually or in combination.

In the case where glass is used as the substrate, use of alkali-free glass is preferable in view of reduction in the amount of ions eluted from the glass. In the case where soda-lime glass is used as the substrate, use of soda-lime glass barrier-coated with silica or the like (e.g. a barrier film substrate) is preferable. In the case where an organic material is used as the substrate, the organic material is preferably favorable in heat resistance, dimensional stability, solvent resistance, electrical insulation and processability.

In the case where a thermoplastic substrate is used, a hard coat layer, an undercoat layer, etc. may be additionally provided if necessary.

### (Method for Producing Organic Electroluminescence Device)

A method of the present invention for producing an organic electroluminescence device is a method for producing the above-mentioned organic electroluminescence device of the present invention, and the method includes a low-refractive-index layer forming step and a lens forming step and may, if necessary, include other step(s) as well.

### <Low-Refractive-Index Layer Forming Step>

The low-refractive-index layer forming step is a step of forming a low-refractive-index layer on a sealing layer which covers a surface of a cathode of an organic electroluminescence portion.

The method for forming the low-refractive-index layer is not particularly limited and may be suitably selected according to the material used for the low-refractive-index layer. In the case of an inorganic fluorine-containing material such as an inorganic fluoride, examples of the method include CVD and vacuum vapor deposition. In the case of an organic fluorine-containing material such as a fluorine resin, examples of the method include spin coating, dip coating and potting.

### <Lens Forming Step>

The lens forming step is a step of forming a lens on a surface of the low-refractive-index layer formed in the low-refractive-index layer forming step.

The method for forming the lens is not particularly limited and may be suitably selected according to the intended purpose. Examples thereof include cutting, polishing, imprinting, ink jetting, photolithography, and combinations of these. Among these, imprinting and ink jetting are particularly preferable.

For example, the imprinting is performed as follows: on the low-refractive-index layer formed on the sealing layer which covers the surface of the cathode of the organic electroluminescence portion, a transparent glass mold having concave portions corresponding to lenses, coated with a release resin and then coated with an acrylic resin, is set so as to fit over pixels of the organic electroluminescence portion and then pressed. Thereafter, the glass mold is removed, and hemispherical lenses can be thus formed.

For example, the ink jetting is performed as follows: on the low-refractive-index layer formed on the sealing layer which covers the surface of the cathode of the organic electroluminescence portion, an SiO₂ film was formed by RF sputtering, with a mask fitted over pixels of the organic electroluminescence portion. Subsequently, UV cleaning is carried out, then an acrylic resin is applied onto the patterned SiO₂ film by ink jetting. Thereafter, UV light is applied to cure the acrylic resin, and hemispherical lenses can be thus formed.

### <Other Step(s)>

Examples of the other step(s) optionally included in the method of the present invention for producing the organic electroluminescence device include a step of forming layers constituting the organic electroluminescence portion.

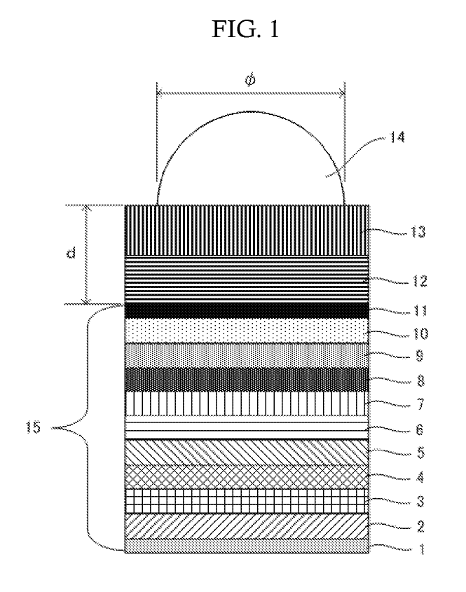

Here, FIG. 1 is referred to, which is a schematic cross-sectional view showing a top emission type organic electroluminescence device that is an example of the organic electroluminescence device of the present invention.

The top emission type organic electroluminescence device shown in FIG. 1 includes: an organic electroluminescence portion 15 composed of an anode 1, a hole injection layer 2, a first hole transport layer 3, a second hole transport layer 4, a third hole transport layer 5, a light-emitting layer 6, a first electron transport layer 7, a second electron transport layer 8, a first electron injection layer 9, a second electron injection layer 10 and a cathode 11; and a sealing layer 12, a low-refractive-index layer 13 and a lens 14 which are provided over the organic electroluminescence portion 15.

The term “light emission direction” means the direction in which light coming from the light-emitting layer is emitted from the light extraction surface toward the outside of the organic electroluminescence device. In the case of the top emission type organic electroluminescence device shown in FIG. 1, the light emission direction means the upward direction parallel to the drawing, as seen from the light-emitting layer 6.

The organic electroluminescence device of the present invention may be constructed as a device capable of full-color display.

Examples of methods of constructing the organic electroluminescence device of the present invention as a full-color type include a tricolor light emission method in which layers that emit lights corresponding to three primary colors (blue (B), green (G) and red (R)) respectively are disposed over a substrate (as described on pp. 33-37 of the September 2000 issue of “Monthly Display”); a white color method in which white light emitted by means of a layer structure for white light emission is passed through a color filter and thus divided into three primary colors; and a color conversion method in which blue light emitted by means of a layer structure for blue light emission is passed through a fluorescent pigment layer and thus converted to red (R) light and green (G) light.

Also, by combining a plurality of layer structures for different light emission colors, obtained by any of the above-mentioned methods, it is possible to obtain a flat-type light source of a desired light emission color. Examples of such a light source include a white emission light source that is a combination of blue and yellow light-emitting elements, and a white emission light source that is a combination of blue, green and red light-emitting elements.

The organic electroluminescence device of the present invention can be suitably used in a variety of fields such as computers, displays for use in vehicles, displays for outdoor use, domestic equipment, equipment for business use, electric household appliances, traffic-related displays, watch/clock displays, calendar displays, luminescent screens and acoustic equipment.

### EXAMPLES

The following explains Examples of the present invention. It should, however, be noted that the scope of the present invention is not confined to these Examples.

### Production Example 1

### Production of Organic Electroluminescence Element (1) (sm=2)

### Top Emission Type, Secondary Microcavity Structure Regarding Optical Length

As a glass substrate, EAGLE 2000 (manufactured by Corning Incorporated) having a thickness of 0.7 mm and a refractive index of 1.5 was used.

Aluminum (Al) as an anode was deposited over the glass substrate by vacuum vapor deposition so as to have a thickness of 100 nm.

Next, 2-TNATA [4,4′,4″-tris(2-naphthylphenylamino)triphenylamine] and MnO₃, as a hole injection layer, were deposited at a proportion of 7:3 over the Al film by vacuum vapor deposition so as to have a thickness of 20 nm.

Next, 2-TNATA doped with 1.0% F4-TCNQ (2,3,5,6-tetrafluoro-7,7,8,8-tetracyanoquinodimethane), as a first hole transport layer, was deposited over the hole injection layer by vacuum vapor deposition so as to have a thickness of 141 nm.

Next, α-NPD [N,N′-(dinaphthylphenylamino)pyrene] as a second hole transport layer was deposited over the first hole transport layer by vacuum vapor deposition so as to have a thickness of 10 nm.

Next, a hole transport material A, represented by the structural formula below, as a third hole transport layer was deposited over the second hole transport layer by vacuum vapor deposition so as to have a thickness of 3 nm.

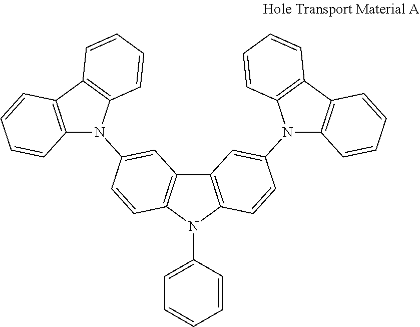

Next, a light-emitting layer, in which CBP (4,4′-dicarbazole-biphenyl) as a host material and a light-emitting material A (represented by the structural formula below) as a light-emitting material were contained at a proportion of 85:15, was deposited over the third hole transport layer by vacuum vapor deposition so as to have a thickness of 20 nm.

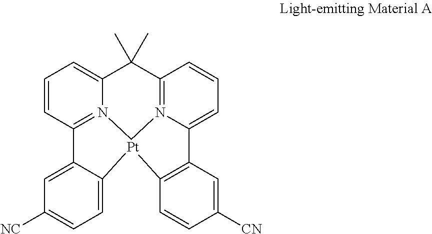

Next, BAlq (aluminum(III)bis(2-methyl-8-quinolinato)-4-phenylphenolate) as a first electron transport layer was deposited overt the light-emitting layer by vacuum vapor deposition so as to have a thickness of 39 nm.

Next, BCP (2,9-dimethyl-4,7-diphenyl-1,10-phenanthroline) as a second electron transport layer was deposited over the first electron transport layer by vacuum vapor deposition so as to have a thickness of 1 nm.

Next, LiF as a first electron injection layer was deposited over the second electron transport layer by vacuum vapor deposition so as to have a thickness of 1 nm.

Next, Al as a second electron injection layer was deposited over the first electron injection layer by vacuum vapor deposition so as to have a thickness of 1 nm.

Next, Ag as a cathode was deposited over the electron injection layers by vacuum vapor deposition so as to have a thickness of 20 nm.

Next, SiON as a sealing layer was deposited over the cathode by vacuum vapor deposition so as to have a thickness of 3,000 nm. In this manner, an organic electroluminescence element (1) was produced.

The organic electroluminescence element (1) had a secondary microcavity structure having an optical length L(λ) of 2λ (λ denotes an emission wavelength).

### Production Example 2

### Production of Organic Electroluminescence Element (2) (sm=3)

### Top Emission Type, Tertiary Microcavity Structure Regarding Optical Length

The same process as in Production Example 1 was carried out except that the thickness of the first hole transport layer was changed from 141 nm to 271 nm. In this manner, an organic electroluminescence element (2) was produced.

The organic electroluminescence element (2) had a tertiary microcavity structure having an optical length L(λ) of 3λ (λ denotes an emission wavelength).

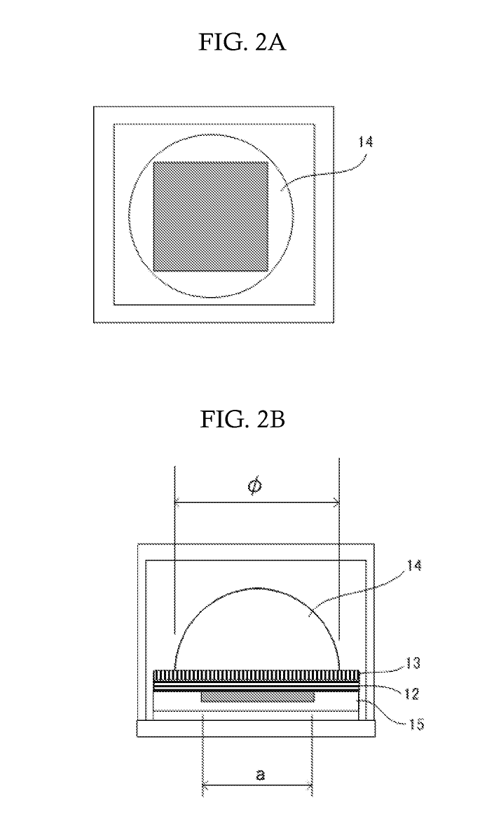

Each organic electroluminescence element produced was optimized for emission of green light (approximately 530 nm), and one side of a light-emitting portion (light-emitting layer) of each organic electroluminescence element had a maximum length “a” (see FIG. 2B) of 2 mm.

Next, regarding each organic electroluminescence element, a cylinder lens having a large enough diameter (10 mm in radius) and a refractive index of 1.8 was installed over the sealing layer as a light extraction surface, using a matching oil (refractive index: 1.8). The luminous intensity distribution of each organic electroluminescence element was measured in the following manner. By evaluating the luminous intensity distribution, it is possible to ascertain the light angular distribution inside the sealing layer.

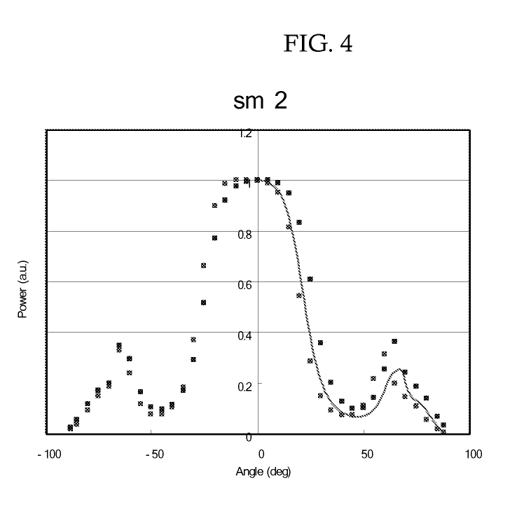

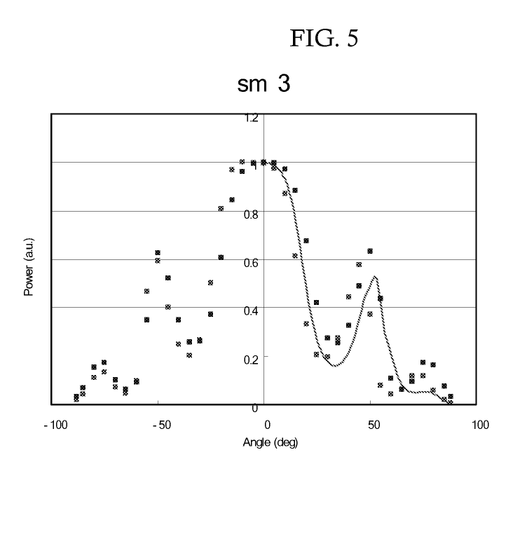

The results of the luminous intensity distributions regarding the organic electroluminescence element (1) (sm=2) and the organic electroluminescence element (2) (sm=3) are shown in FIGS. 4 and 5 respectively.

### <Method of Measuring Luminous Intensity Distribution>

A silicon detector (S4349, manufactured by Hamamatsu Photonics K.K.) was attached to a goniometer (self-produced), each organic electroluminescence element was made to emit light, then the relationship between an angle indicated by the goniometer and a voltage signal corresponding to the light intensity indicated by the silicon detector was measured, and the luminous intensity distribution was thus calculated.

In the case where a lens as a light extraction component is not attached to each organic electroluminescence element, the total reflection angle at the interface between the sealing layer and the air is ±33°, and light is not emitted at any angles greater than ±33° into the air.

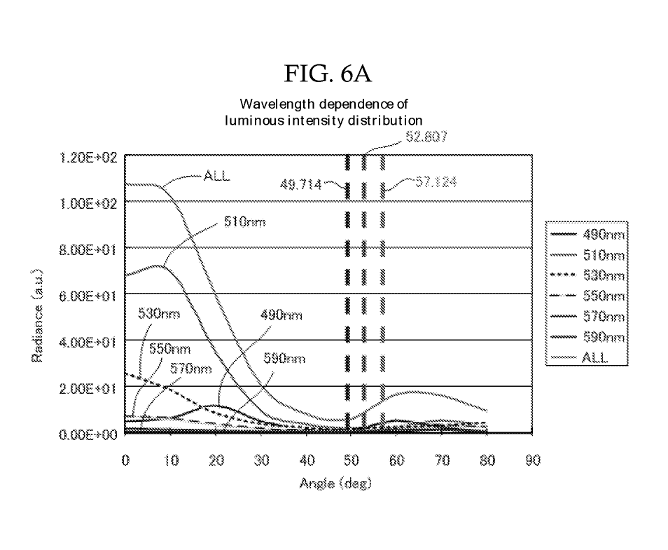

The results shown in FIGS. 4 and 5 demonstrate that the front luminance was high, but there was a secondary peak on the high angle side, so that there was a bright part found when seen from a diagonal direction, which led to unnaturalness. Further, regarding the wavelength dependence of the luminous intensity distribution, the results shown in FIGS. 6A and 6B (the wavelength of 510 nm shown in FIG. 6A is set at 1.0 in FIG. 6B) demonstrate that long-wavelength light components abounded at angles greater than or equal to 50°, and thus a color change was noticed when seen from a diagonal direction, which led to unnaturalness.

### Example 1

### Production of Organic Electroluminescence Device

### —No. 1—

An organic electroluminescence device of No. 1 was an organic electroluminescence device in which neither a low-refractive-index layer nor lenses were provided over the sealing layer which covered the surface of the cathode of the organic electroluminescence element (1) of Production Example 1 (in other words, the organic electroluminescence element (1) itself).

### —No. 2—

An organic electroluminescence device of No. 2 was produced as follows. A glass material 1 (S-LAH53, manufactured by OHARA INC.; refractive index: 1.81) as a low-refractive-index layer was deposited by RF sputtering on the sealing layer which covered the surface of the cathode of the organic electroluminescence element (1) of Production Example 1, such that the low-refractive-index layer had a thickness of 3,000 nm.

Next, a glass material 1 (S-LAH53, manufactured by OHARA INC.; refractive index: 1.81) was deposited on the low-refractive-index layer by RF sputtering so as to have a thickness of 3,000 nm. By cutting the obtained glass layer, hemispherical lenses (refractive index: 1.81) were formed.

### —No. 3—

An organic electroluminescence device of No. 3 was produced as follows. A glass material 2 (BK7, manufactured by SCHOTT AG; refractive index: 1.52) as a low-refractive-index layer was deposited by RF sputtering on the sealing layer which covered the surface of the cathode of the organic electroluminescence element (1) of Production Example 1, such that the low-refractive-index layer had a thickness of 3,000 nm.

Next, a glass material 2 (BK7, manufactured by SCHOTT AG; refractive index: 1.52) was deposited on the low-refractive-index layer by RF sputtering so as to have a thickness of 3,000 nm. By cutting the obtained glass layer, hemispherical lenses (refractive index: 1.52) were formed.

### —No. 4—

An organic electroluminescence device of No. 4 was produced as follows. A glass material 3 (S-FPL53, manufactured by OHARA INC.; refractive index: 1.44) as a low-refractive-index layer was deposited by RF sputtering on the sealing layer which covered the surface of the cathode of the organic electroluminescence element (1) of Production Example 1, such that the low-refractive-index layer had a thickness of 3,000 nm.

Next, a glass material 3 (S-FPL53, manufactured by OHARA INC.; refractive index: 1.44) was deposited on the low-refractive-index layer by RF sputtering so as to have a thickness of 3,000 nm. By cutting the obtained glass layer, hemispherical lenses (refractive index: 1.44) were formed.

### —No. 5—

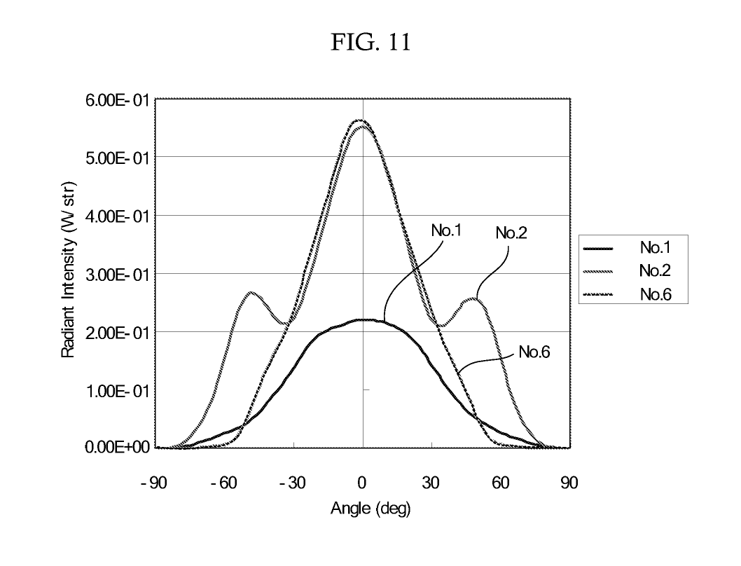

An organic electroluminescence device of No. 5 was produced as follows. As shown in FIG. 12, an inorganic fluoride (MgF₂; refractive index: 1.38) as a low-refractive-index layer was deposited by vacuum vapor deposition on the sealing layer which covered the surface of the cathode of the organic electroluminescence element (1) of Production Example 1, such that the low-refractive-index layer had a thickness of 3,000 nm.

Next, on the low-refractive-index layer, a transparent glass mold having concave portions corresponding to lenses, coated with a release resin and then coated with an acrylic resin 1 (refractive index: 1.38), was set so as to fit over pixels of the organic electroluminescence element and then pressed. Thereafter, the glass mold was removed, and hemispherical lenses (refractive index: 1.38) were thus formed.

### —No. 6—

An organic electroluminescence device of No. 6 was produced as follows. As shown in FIG. 12, an inorganic fluoride (MgF₂; refractive index: 1.38) as a low-refractive-index layer was deposited by vacuum vapor deposition on the sealing layer which covered the surface of the cathode of the organic electroluminescence element (1) of Production Example 1, such that the low-refractive-index layer had a thickness of 3,000 nm.

Next, on the low-refractive-index layer, a transparent glass mold having concave portions corresponding to lenses, coated with a release resin and then coated with an acrylic resin 2 (refractive index: 1.81), was set so as to fit over pixels of the organic electroluminescence element and then pressed. Thereafter, the glass mold was removed, and hemispherical lenses (refractive index: 1.81) were thus formed.

### —No. 7—

An organic electroluminescence device of No. 7 was produced as follows. As shown in FIG. 12, an inorganic fluoride (MgF₂; refractive index: 1.38) as a low-refractive-index layer was deposited by vacuum vapor deposition on the sealing layer which covered the surface of the cathode of the organic electroluminescence element (1) of Production Example 1, such that the low-refractive-index layer had a thickness of 3,000 nm.

Next, on the low-refractive-index layer, a transparent glass mold having concave portions corresponding to lenses, coated with a release resin and then coated with an acrylic resin 3 (refractive index: 1.52), was set so as to fit over pixels of the organic electroluminescence element and then pressed. Thereafter, the glass mold was removed, and hemispherical lenses (refractive index: 1.52) were thus formed.

### —No. 8—

An organic electroluminescence device of No. 8 was produced as follows. As shown in FIG. 12, an inorganic fluoride (MgF₂; refractive index: 1.38) as a low-refractive-index layer was deposited by vacuum vapor deposition on the sealing layer which covered the surface of the cathode of the organic electroluminescence element (1) of Production Example 1, such that the low-refractive-index layer had a thickness of 3,000 nm.

Next, on the low-refractive-index layer, a transparent glass mold having concave portions corresponding to lenses, coated with a release resin and then coated with an acrylic resin 4 (refractive index: 1.44), was set so as to fit over pixels of the organic electroluminescence element and then pressed. Thereafter, the glass mold was removed, and hemispherical lenses (refractive index: 1.44) were thus formed.

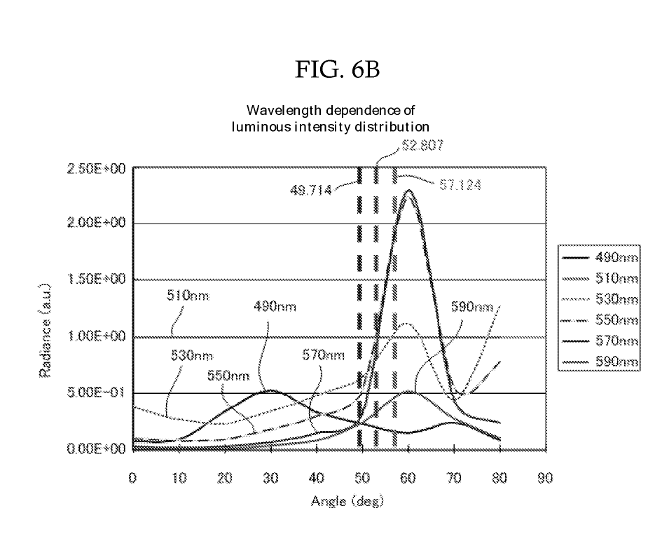

Regarding each of the organic electroluminescence devices of Nos. 1 to 8 thus produced, the angular distribution of light intensity was examined. As shown in FIGS. 2A and 2B, the maximum length “a” of one side of a light-emitting portion (light-emitting layer) was 2 mm, and the effective diameter φ of a lens was 3 mm. The results are shown in Table 1 and FIGS. 7 to 10.

The results shown in Table 7 demonstrate that when the refractive index nf of the low-refractive-index layer and the refractive index nL of each lens were equal as in the cases of Nos. 1 to 5, a secondary peak on the high angle side could be removed provided that the refractive index of each lens was small, as shown by Nos. 2 to 5; however, there was a decrease in front luminance.

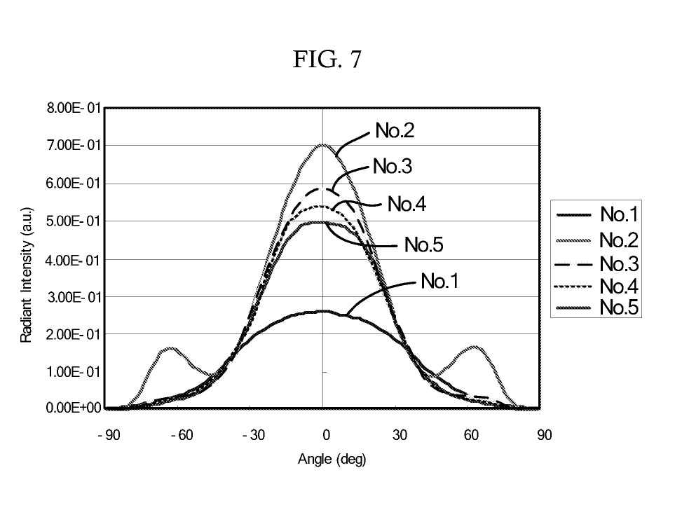

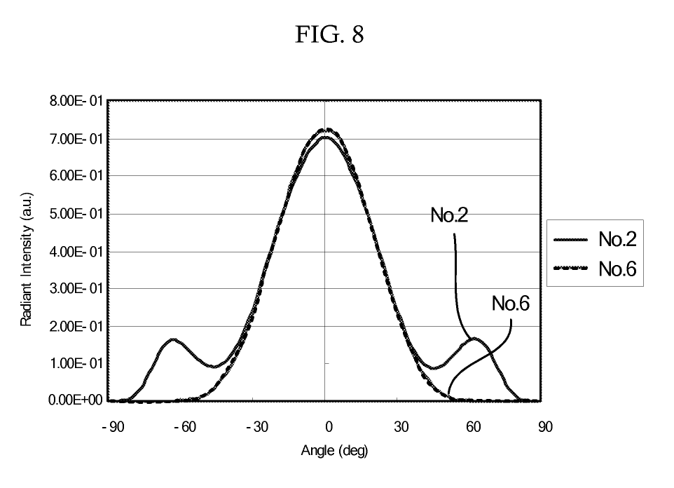

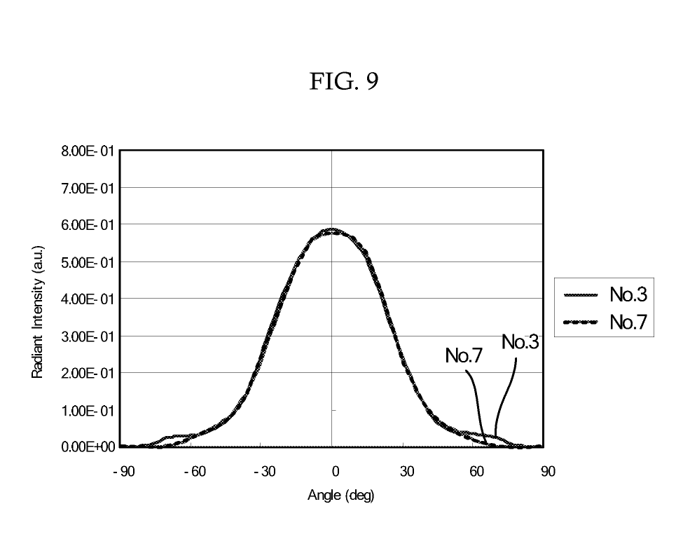

Next, the results obtained when the refractive index nL of each lens was fixed at 1.38 and the refractive index nf of the low-refractive-index layer was set at 1.81, 1.52 and 1.44 as indicated by Nos. 6 to 8 are shown in FIGS. 8 to 10. FIG. 8 shows the results obtained when No. 2 and No. 6 were compared. FIG. 9 shows the results obtained when No. 3 and No. 7 were compared. FIG. 10 shows the results obtained when No. 4 and No. 8 were compared. These results demonstrate that a secondary peak on the high angle side could be removed with the front luminance being the same as in the case of nf=nL.

Therefore, it was found that it was important to satisfy the following relationships: Refractive index np of sealing layer>Refractive index nf of low-refractive-index layer; Refractive index nL of lens>Refractive index nf of low-refractive-index layer.

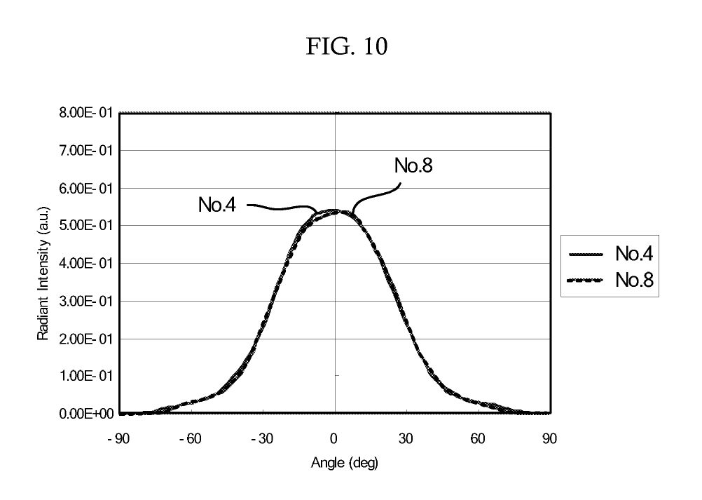

Meanwhile, using the organic electroluminescence element (2) produced in Production Example 2 (instead of using the organic electroluminescence element (1) produced in Production Example 1), organic electroluminescence devices of Nos. 1, 2 and 6 were produced as in Example 1, and the angular distribution of light intensity regarding each organic electroluminescence device was examined as in Example 1. The results are shown in FIG. 11.

The results shown in FIG. 11 demonstrate that the organic electroluminescence element (2) (with a tertiary microcavity structure) produced in Production Example 2 could yield results similar to those yielded by the organic electroluminescence element (1) produced in Production Example 1.

TABLE 1

| | | | Low-refractive -index | | | | | | |
|---|---|---|---|---|---|---|---|---|---|
| | Sealing layer | | layer | | Lens | | | | |
| | | Refractive | | Refractive | | Refractive | | | Reference |
| No. | Material | index (np) | Material | index (nf) | Material | index (nL) | θm | θp | column |
| 1 | SiON | 1.78 | Not | 1.00 | Not | 1.00 | 33.62 | 34.18 | Basic |
| | | | provided | | provided | | | | |
| 2 | SiON | 1.78 | S-LAH53 | 1.81 | S-LAH53 | 1.81 | 90.00 | 34.18 | Conventional |
| 3 | SiON | 1.78 | BK7 | 1.52 | BK7 | 1.52 | 57.12 | 34.18 | Comparison |
| | | | | | | | | | 1 |
| 4 | SiON | 1.78 | S-FPL53 | 1.44 | S-FPL53 | 1.44 | 52.81 | 34.18 | Comparison |
| | | | | | | | | | 2 |
| 5 | SiON | 1.78 | MgF₂ | 1.38 | Acrylic | 1.38 | 49.71 | 34.18 | Comparison |
| | | | | | resin 1 | | | | 3 |
| 6 | SiON | 1.78 | MgF₂ | 1.38 | Acrylic | 1.81 | 49.71 | 34.18 | Present |
| | | | | | resin 2 | | | | invention 1 |
| 7 | SiON | 1.78 | MgF₂ | 1.38 | Acrylic | 1.52 | 49.71 | 34.18 | Present |
| | | | | | resin 3 | | | | invention 2 |
| 8 | SiON | 1.78 | MgF₂ | 1.38 | Acrylic | 1.44 | 49.71 | 34.18 | Present |
| | | | | | resin 4 | | | | invention 3 |

### Example 2

### Production of Organic Electroluminescence Device

### —No. 9—

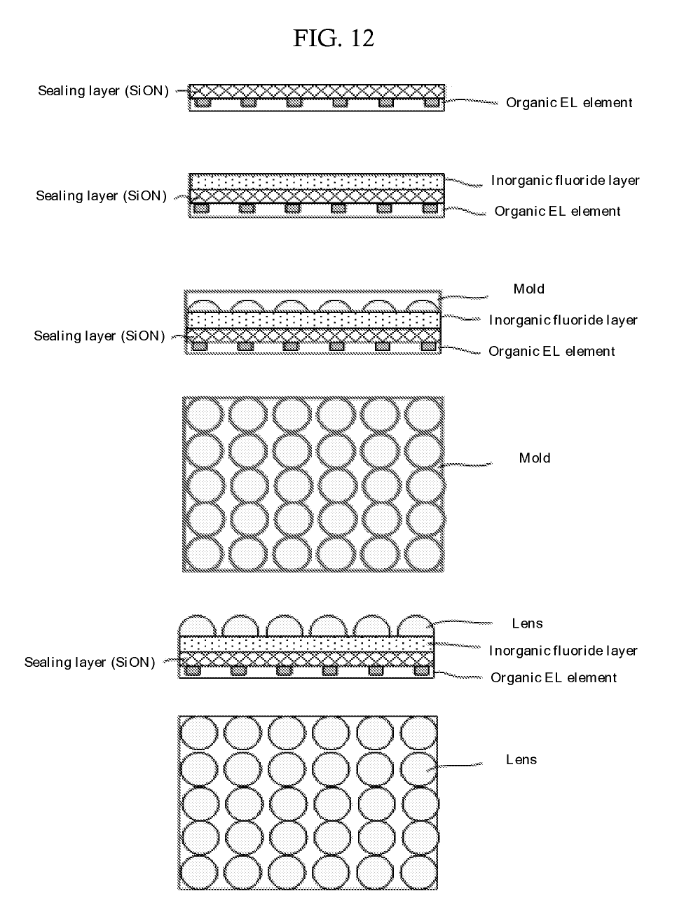

An organic electroluminescence device of No. 9 was produced as follows. As shown in FIG. 13, a fluorine resin (CYTOP, manufactured by ASAHI GLASS CO., LTD.; refractive index: 1.38) as a low-refractive-index layer was deposited by spin coating on the sealing layer which covered the surface of the cathode of the organic electroluminescence element (1) of Production Example 1, such that the low-refractive-index layer had a thickness of 3,000 nm. Subsequently, post-baking was carried out at 150° C. or lower.

Next, on the low-refractive-index layer, an SiO₂ film was formed by RF sputtering so as to have a thickness of 100 nm, with a mask fitted over pixels of the organic electroluminescence element. Subsequently, UV cleaning was carried out, then an acrylic resin 1 (refractive index: 1.38) was applied onto the patterned SiO₂ film by ink jetting. Thereafter, UV light was applied to cure the acrylic resin, and hemispherical lenses (refractive index: 1.38) were thus formed.

### —No. 10—

An organic electroluminescence device of No. 10 was produced as follows. As shown in FIG. 13, a fluorine resin (CYTOP, manufactured by ASAHI GLASS CO., LTD.; refractive index: 1.38) as a low-refractive-index layer was deposited by spin coating on the sealing layer which covered the surface of the cathode of the organic electroluminescence element (1) of Production Example 1, such that the low-refractive-index layer had a thickness of 3,000 nm. Subsequently, post-baking was carried out at 150° C. or lower.

Next, on the low-refractive-index layer, an SiO₂ film was formed by RF sputtering so as to have a thickness of 100 nm, with a mask fitted over pixels of the organic electroluminescence element. Subsequently, UV cleaning was carried out, then an acrylic resin 2 (refractive index: 1.81) was applied onto the patterned SiO₂ film by ink jetting. Thereafter, UV light was applied to cure the acrylic resin, and hemispherical lenses (refractive index: 1.81) were thus formed.

### —No. 11—

An organic electroluminescence device of No. 11 was produced as follows. As shown in FIG. 13, a fluorine resin (CYTOP, manufactured by ASAHI GLASS CO., LTD.; refractive index: 1.38) as a low-refractive-index layer was deposited by spin coating on the sealing layer which covered the surface of the cathode of the organic electroluminescence element (1) of Production Example 1, such that the low-refractive-index layer had a thickness of 3,000 nm. Subsequently, post-baking was carried out at 150° C. or lower.

Next, on the low-refractive-index layer, an SiO₂ film was formed by RF sputtering so as to have a thickness of 100 nm, with a mask fitted over pixels of the organic electroluminescence element. Subsequently, UV cleaning was carried out, then an acrylic resin 3 (refractive index: 1.52) was applied onto the patterned SiO₂ film by ink jetting. Thereafter, UV light was applied to cure the acrylic resin, and hemispherical lenses (refractive index: 1.52) were thus formed.

### —No. 12—

An organic electroluminescence device of No. 12 was produced as follows. As shown in FIG. 13, a fluorine resin (CYTOP, manufactured by ASAHI GLASS CO., LTD.; refractive index: 1.38) as a low-refractive-index layer was deposited by spin coating on the sealing layer which covered the surface of the cathode of the organic electroluminescence element (1) of Production Example 1, such that the low-refractive-index layer had a thickness of 3,000 nm. Subsequently, post-baking was carried out at 150° C. or lower.

Next, on the low-refractive-index layer, an SiO₂ film was formed by RF sputtering so as to have a thickness of 100 nm, with a mask fitted over pixels of the organic electroluminescence element. Subsequently, UV cleaning was carried out, then an acrylic resin 4 (refractive index: 1.44) was applied onto the patterned SiO₂ film by ink jetting. Thereafter, UV light was applied to cure the acrylic resin, and hemispherical lenses (refractive index: 1.44) were thus formed.

Regarding each of the organic electroluminescence devices of Nos. 9 to 12 thus produced, the angular distribution of light intensity was examined as in Example 1. The size of a light-emitting layer was 2 mm×2 mm, and the radius of a lens was 3 mm. The results obtained were similar to those shown in FIGS. 7 to 10.

Meanwhile, using the organic electroluminescence element (2) produced in Production Example 2 (instead of using the organic electroluminescence element (1) produced in Production Example 1), organic electroluminescence devices of Nos. 1, 2 and 10 were produced as in Example 2, and the angular distribution of light intensity regarding each organic electroluminescence device was examined as in Example 1. The results obtained were similar to those shown in FIG. 11.

TABLE 2

| | | | Low-refractive-index | | | | | | |
|---|---|---|---|---|---|---|---|---|---|
| | Sealing layer | | layer | | Lens | | | | |
| | | Refractive | | Refractive | | Refractive | | | Reference |
| No. | Material | index (np) | Material | index (nf) | Material | index (nL) | θm | θp | column |
| 1 | SiON | 1.78 | Not | 1.00 | Not | 1.00 | 33.62 | 34.18 | Basic |
| | | | provided | | provided | | | | |
| 2 | SiON | 1.78 | S-LAH53 | 1.81 | S-LAH53 | 1.81 | 90.00 | 34.18 | Conventional |
| 3 | SiON | 1.78 | BK7 | 1.52 | BK7 | 1.52 | 57.12 | 34.18 | Comparison |
| | | | | | | | | | 1 |
| 4 | SiON | 1.78 | S-FPL53 | 1.44 | S-FPL53 | 1.44 | 52.81 | 34.18 | Comparison |
| | | | | | | | | | 2 |
| 9 | SiON | 1.78 | Fluorine | 1.38 | Acrylic | 1.38 | 49.71 | 34.18 | Comparison |
| | | | resin | | resin 1 | | | | 3 |
| 10 | SiON | 1.78 | Fluorine | 1.38 | Acrylic | 1.81 | 49.71 | 34.18 | Present |
| | | | resin | | resin 2 | | | | invention 4 |
| 11 | SiON | 1.78 | Fluorine | 1.38 | Acrylic | 1.52 | 49.71 | 34.18 | Present |
| | | | resin | | resin 3 | | | | invention 5 |
| 12 | SiON | 1.78 | Fluorine | 1.38 | Acrylic | 1.44 | 49.71 | 34.18 | Present |
| | | | resin | | resin 4 | | | | invention 6 |

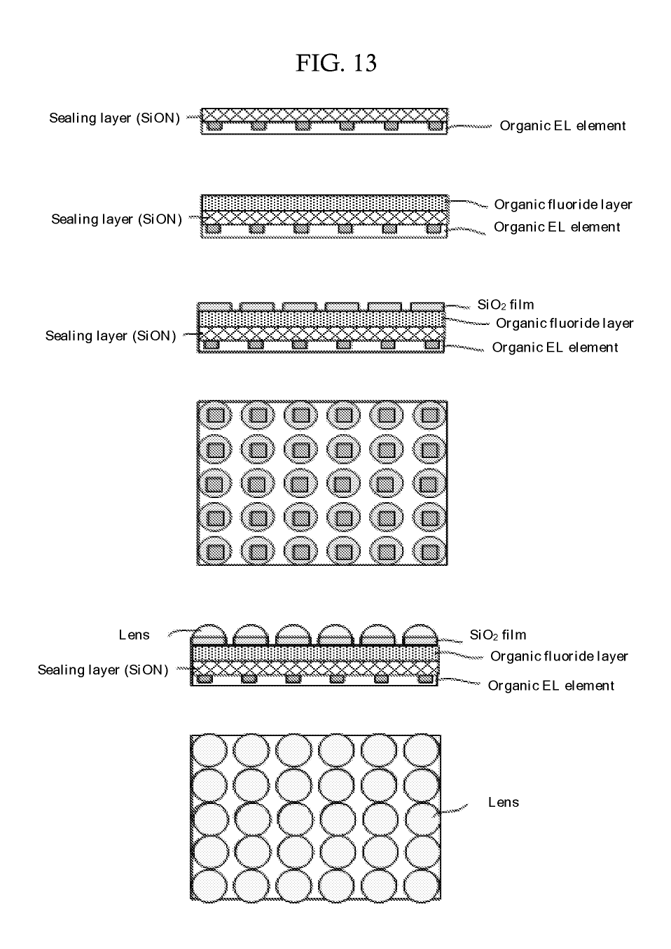

Next, regarding the organic electroluminescence element regarding Production Example 1, the angular distribution of light intensity was examined, when the ratio of the effective diameter φ of each lens to the distance d between the cathode of the organic electroluminescence portion and the lens, represented by φ/d, was set at 1, 2, 6, 15 and 30. The results are shown in FIG. 14.

The results shown in FIG. 14 demonstrate that, in order to maintain a single peak, the ratio of the effective diameter φ of each lens to the distance d between the cathode of the organic electroluminescence portion and the lens, represented by φ/d, was preferably 2 or greater.

The results of Examples 1 and 2 explained above are to do with one green pixel (wavelength: approximately 530 nm). It should be noted that similar results were obtained regarding a blue pixel (wavelength: approximately 470 nm) and a red pixel (wavelength: approximately 630 nm).

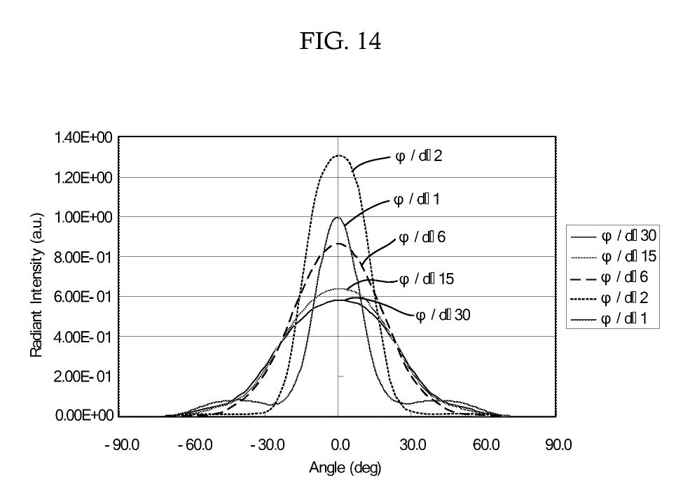

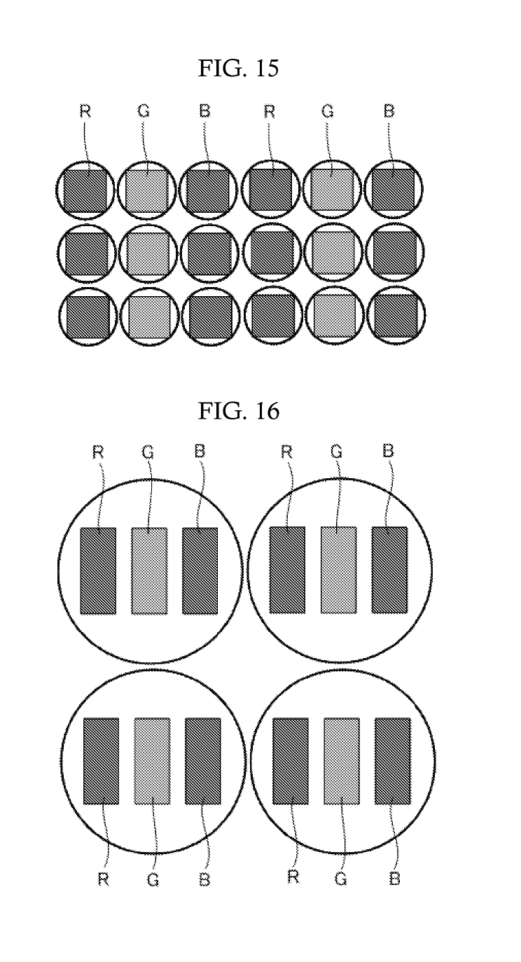

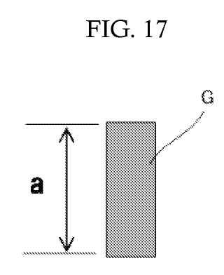

In the case where a device having three-color pixels of RGB (R: red, G: green, B: blue) is produced and lenses are placed for the three-color pixels of RGB, each of the three-color pixels of RGB may be surrounded by a lens as shown in FIG. 15, or units which are each composed of three-color pixels of RGB may be surrounded by lenses as shown in FIG. 16. In the case where a pixel is not a square but a rectangle with sides of different lengths as shown in FIG. 17, the longer side is defined as the maximum length “a” of one side of a light-emitting portion (light-emitting layer).

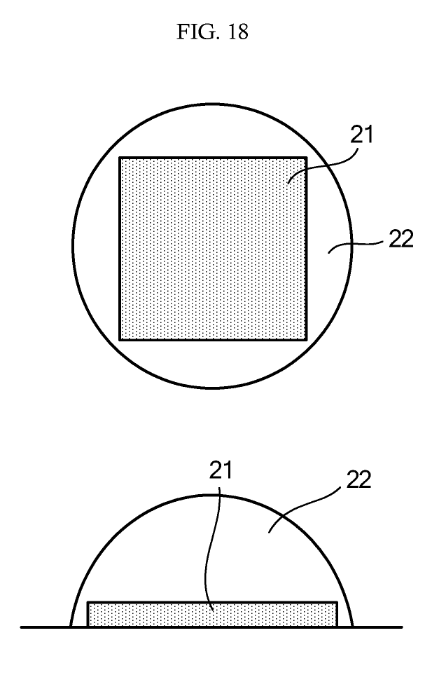

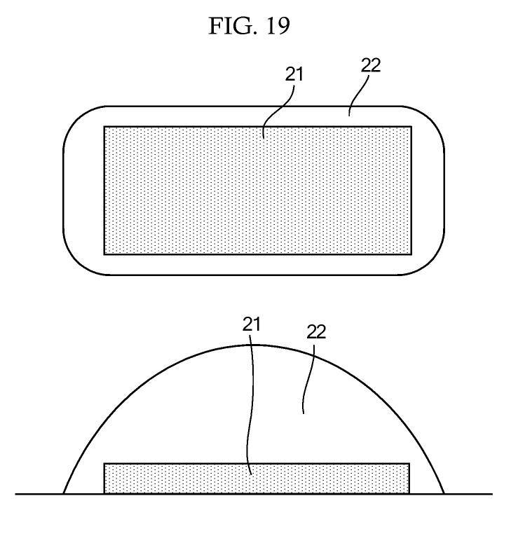

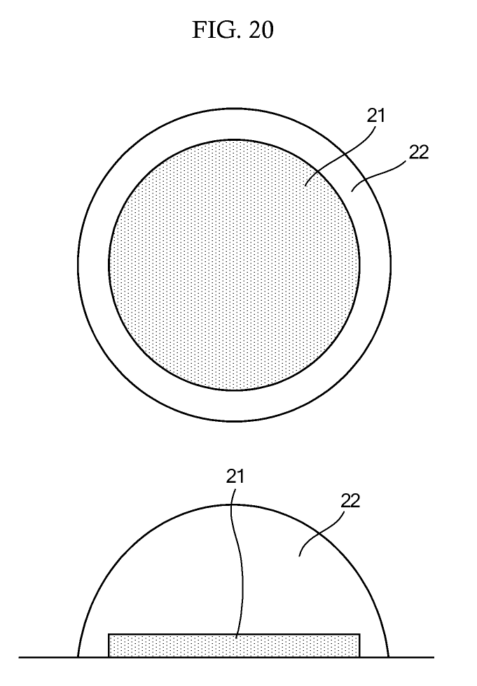

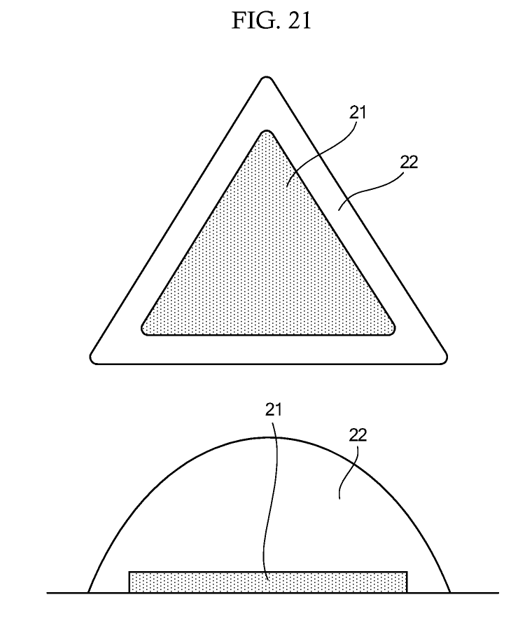

Also, the pixel shape is not particularly limited and may be suitably selected according to the intended purpose. For example, there are an aspect in which a lens 22 is placed over a square pixel 21 as shown in FIG. 18, an aspect in which a lens 22 is placed over a rectangular pixel 21 as shown in FIG. 19, an aspect in which a lens 22 is placed over a circular pixel 21 as shown in FIG. 20, and an aspect in which a lens 22 is placed over a triangular pixel 21 as shown in FIG. 21.

In Examples 1 and 2, the organic electroluminescence devices in which the maximum length “a” of one side of a light-emitting portion (light-emitting layer) was 2 mm were produced and evaluated. Here, it should be noted that the optical properties of the organic electroluminescence devices can be made constant provided that the ratio (φ/a) is maintained.

In fact, an organic EL element in which the maximum length “a” of one side of a light-emitting portion (light-emitting layer) was 2 μm was produced and similarly evaluated. On this occasion, an experiment was carried out using a glass substrate having a thickness (d) of 20 μm. As a result, optical properties were obtained which were similar to those obtained in the case where the maximum length “a” of one side of a light-emitting portion (light-emitting layer) was 2 mm.

An organic electroluminescence device of the present invention can be suitably used in a variety of fields such as computers, displays for use in vehicles, displays for outdoor use, domestic equipment, equipment for business use, electric household appliances, traffic-related displays, watch/clock displays, calendar displays, luminescent screens and acoustic equipment.

What is claimed is:

1. An organic electroluminescence device comprising:
an organic electroluminescence portion which includes at least an anode, a light-emitting layer and a cathode;
a sealing layer which covers a surface of the cathode of the organic electroluminescence portion;
a lens which is provided over the sealing layer and controls an optical path of light emitted from the light-emitting layer; and
a low-refractive-index layer provided between the sealing layer and the lens,
wherein the low-refractive-index layer has a refractive index lower than a refractive index of the sealing layer.

2. The organic electroluminescence device according to claim 1, wherein the low-refractive-index layer is a solid layer having a low refractive index.

3. The organic electroluminescence device according to claim 1, wherein the lens has a refractive index higher than the refractive index of the low-refractive-index layer.

4. The organic electroluminescence device according to claim 1, wherein a luminous intensity distribution in the sealing layer has a plurality of peaks, and
wherein a peak angle θp of the sealing layer with respect to a higher angle side than a main peak, and a total reflection angle θm of the sealing layer calculated as θm=sin⁻¹(nf/np) satisfy the relationship θm<θp,
where np denotes the refractive index of the sealing layer, and of denotes the refractive index of the low-refractive-index layer.

5. The organic electroluminescence device according to claim 1, wherein the ratio of an effective diameter φ of the lens to a distance d between the cathode of the organic electroluminescence portion and the lens, represented by φ/d, is 2 or greater.

6. The organic electroluminescence device according to claim 1, wherein the organic electroluminescence portion has a secondary microcavity structure having an optical length L(λ) of 2λ,
where λ denotes an emission wavelength.

7. The organic electroluminescence device according to claim 1, wherein the organic electroluminescence portion has a tertiary microcavity structure having an optical length L(λ) of 3λ,
where λ denotes an emission wavelength.

8. The organic electroluminescence device according to claim 1, wherein the low-refractive-index layer contains a fluorine-containing material.

9. A method for producing an organic electroluminescence device, comprising:
forming a low-refractive-index layer on a sealing layer which covers a surface of a cathode of an organic electroluminescence portion; and
forming a lens on a surface of the low-refractive-index layer,
wherein the organic electroluminescence device comprises:
the organic electroluminescence portion which includes at least an anode, a light-emitting layer and the cathode;
the sealing layer which covers the surface of the cathode of the organic electroluminescence portion;
the lens which is provided over the sealing layer and controls an optical path of light emitted from the light-emitting layer; and
the low-refractive-index layer provided between the sealing layer and the lens, and
wherein the low-refractive-index layer has a refractive index lower than a refractive index of the sealing layer.

10. The method according to claim 9, wherein the lens is formed by imprinting.

11. The method according to claim 9, wherein the lens is formed by ink jetting.
